(19) United States
(12) Patent Application Publication
(10) Pub. No.: US 2018/0108732 A1
(43) Pub. Date: Apr. 19, 2018

(54) NOTCHED FIN STRUCTURES AND METHODS OF MANUFACTURE

(71) Applicant: GLOBALFOUNDRIES INC., Grand Cayman (KY)

(72) Inventors: Jiehui Shu, Clifton Park, NY (US); Baofu Zhu, Clifton Park, NY (US); Haifeng Sheng, Rexford, NY (US); Jinping Liu, Ballston Lake, NY (US); Shesh Mani Pandey, Saratoga Springs, NY (US); Jagar Singh, Clifton Park, NY (US)

(21) Appl. No.: 15/292,808

(22) Filed: Oct. 13, 2016

(51) Int. Cl. H01L 29/06; H01L 29/78; H01L 21/306; H01L 29/66

(52) U.S. Cl. CPC H01L 29/0661; H01L 29/785; H01L 29/66795; H01L 21/30604; H01L 29/7849

(57) ABSTRACT

The present disclosure relates to semiconductor structures and, more particularly, to notched fin structures and methods of manufacture. The structure includes: a fin structure composed of a substrate material and a stack of multiple epitaxially grown materials on the substrate material; a notch formed in a first epitaxially grown material of the stack of multiple epitaxially grown materials of the fin structure; an insulator material within the notch of the fin structure; and an insulator layer surrounding the fin structure and above a surface of the notch.

### FIELD OF THE INVENTION

The present disclosure relates to semiconductor structures and, more particularly, to notched fin structures and methods of manufacture.

### BACKGROUND

FinFET devices are three dimensional structures which may be used and other types of semiconductor device applications. FinFET devices typically include semiconductor fins with high aspect ratios which form the body of the device. The thickness of the fin (measured in the direction from source to drain) determines the effective channel length of the device. The increased surface area of the channel and source/drain regions in a finFET results in faster, more reliable and better-controlled semiconductor transistor devices. For example, the wrap-around gate structure provides a better electrical control over the channel and thus helps in reducing the leakage current and overcoming other short-channel effects.

There are many challenges in finFET technology, though. For example, the channel is usually formed from bulk substrate and is susceptible to a channel punch-through effect at the bottom of the transistor. Channel punch-through is a condition in which the depletion layers of the source and the drain connect to each other through the substrate. At low gate voltages, the punch-through current can result in premature breakdown of the finFET. Leakage can also occur in bulk substrate applications; however, this problem can e solved using Silicon-On-Insulator (SOI) substrates which can isolate the leakage issues.

### SUMMARY

In an aspect of the disclosure, a structure comprises: a fin structure composed of a substrate material and a stack of multiple epitaxially grown materials on the substrate material; a notch formed in a first epitaxially grown material of the stack of multiple epitaxially grown materials of the fin structure; an insulator material within the notch of the fin structure; and an insulator layer surrounding the fin structure and above a surface of the notch.

In an aspect of the disclosure, a structure comprises: a fin structure composed of a substrate, a first semiconductor material on the substrate and a second semiconductor material on the first semiconductor material; a notch formed in the first semiconductor material of the fin structure; and an insulator material within the notch of the fin structure and surrounding the substrate, the first semiconductor material and a portion of the second semiconductor material of the fin structure.

In an aspect of the disclosure, a method comprises: forming a fin structure composed of selectively etchable materials: forming a notch in the fin structure by using a selective etching process to one of the selectively etchable materials of the fin structure; filling in the notch and surrounding portions of the fin structure with an insulator material; and recessing the insulator material surrounding portions of the fin structure to below a surface of the fin structure and above the notch.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIGS. 1A-1D show structures and respective fabrication processes for forming a notched fin structure in accordance with aspects of the present disclosure.

FIGS. 2A-2B show structures and respective fabrication processes for forming a notched fin structure in accordance with additional aspects of the present disclosure.

FIGS. 3A-3E show structures and respective fabrication processes for forming a notched fin structure in accordance with additional aspects of the present disclosure.

FIGS. 4A-4C show structures and respective fabrication processes for forming a notched fin structure in accordance with additional aspects of the present disclosure.

FIGS. 5A-5F show structures and respective fabrication processes for forming a notched fin structure in accordance with additional aspects of the present disclosure.

### DETAILED DESCRIPTION

The present disclosure relates to semiconductor structures and, more particularly, to notched fin structures and methods of manufacture. More specifically, the present disclosure provides a finFET structure with a notched profile. In embodiments, the finFET structure with a notched profile will be formed using BULK Si technologies.

Advantageously, the present disclosure provides improved device performance, similar to that which can be provided with Silicon-On-Insulator (SOI) substrates.

In embodiments, the notched finFET structures described herein will not be affected by channel punch-through effect and, hence, will not suffer premature breakdown. That is, the notched finFET structures described herein reduce the channel punch-through effect by varying a width portion of the fin structure. By way of example, by implementing the different embodiments described herein, DC performance of both PFET and NFET devices can be improved due to higher Ieff@Vtsat. The Ring Oscillator (RO) performance is also improved, coming from both DC performance improvement and capacitor reduction.

The notched finFET structures of the present disclosure can be manufactured in a number of ways using a number of different tools. In general, though, the methodologies and tools are used to form structures with dimensions in the micrometer and nanometer scale. The methodologies, i.e., technologies, employed to manufacture the notched finFET structures of the present disclosure have been adopted from integrated circuit (IC) technology. For example, the notched finFET structures are built on wafers and are realized in films of material patterned by photolithographic processes on the top of a wafer. In particular, the fabrication of the notched finFET structures uses three basic building blocks: (i) deposition of thin films of material on a substrate, (ii) applying a patterned mask on top of the films by photolithographic imaging, and (iii) etching the films selectively to the mask.

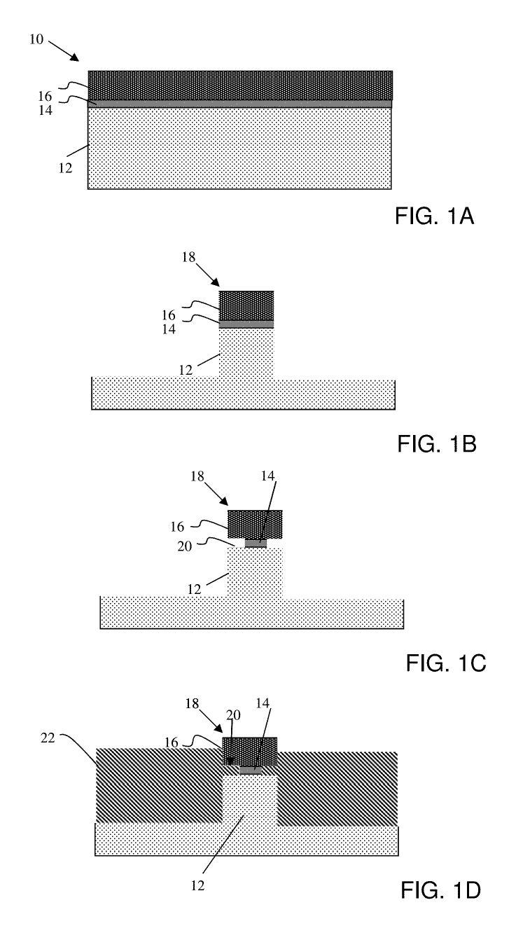

FIGS. 1A-1D show structures and respective fabrication processes for forming a notched fin structure in accordance with aspects of the present disclosure. More specifically, FIG. 1A shows a beginning structure 10 comprising a substrate 12 of semiconductor material, e.g., BULK Si. A semiconductor material 14 is epitaxially grown on the substrate 12. In embodiments, the semiconductor material 14 can be SiGe; although other semiconductor materials are also contemplated herein which are selective to the material of the substrate 12. For example, the semiconductor material 14 can be any material that is selective to the substrate 12 and capable of being epitaxially grown on the substrate 12, e.g., SiGeC, SiC, SiP, GaAs, InAs, InP, etc.

Still referring to FIG. 1A, a semiconductor material 16 is grown directly on the semiconductor material 14. In embodiments, the semiconductor material 16 is preferably the same material as the substrate 12, and is preferably epitaxially grown in order to have a crystalline structure. The semiconductor material 16 should be a different material than the semiconductor material 14, though, such that a selective etching process can be performed to the semiconductor material 14 at later processing steps.

FIG. 1B shows a fin structure 18 and respective processing steps in accordance with aspects of the present disclosure. The fin structure 18 includes layers 12, 14 and 16 and can be fabricated with different dimensions depending on the particular technology node. For example, the dimensions of the fin structure 18 can range from about 7 nm to about 14 nm; although other dimensions are contemplated herein.

In embodiments, the fin structure 18 can be formed by a conventional sidewall image transfer (SIT) technique. In the SIT technique, for example, a mandrel material, e.g., SiO₂, is formed on the semiconductor material 16 using conventional deposition processes. A resist is formed on the mandrel material and exposed to light to form a pattern (openings). A reactive ion etching (RIE) is performed through the openings to form mandrels. In embodiments, the mandrels can have different widths and/or spacing depending on the desired dimensions between the fin structures 18. Spacers are formed on the sidewalls of the mandrels which are preferably material that is different than the mandrels, and which are formed using conventional deposition processes known to those of skill in the art. The spacers can have a width which matches the dimensions of the fin structures 18, for example. The mandrels are removed or stripped using a conventional etching process, selective to the mandrel material. An etching is then performed within the spacing of the spacers to form the sub-lithographic features, e.g., fin structures 18. The sidewall spacers can then be stripped. In embodiments, the fin structure 18 can also be formed during this or other patterning processes, or through other conventional patterning processes, as contemplated by the present disclosure.

In FIG. 1C, a notch 20 is formed in the fin structure 18 using a selective etch process. Specifically, the notch 20 can be formed by a wet or dry etch process with chemistries that are selective to the semiconductor material 14. In embodiments, the notch 20 can be about 25% of the width of the fin structure 18 depending on the technology node; although other dimensions are also contemplated based on specific device performance requirements.

As shown in FIG. 1D, an insulator material 22 is formed within the notch 20 and about the fin structure 18. In embodiments, the insulator material 22 is an oxide material that is formed by an STI oxide gap fill process. Specifically, the insulator material 22 can be deposited within the notch 20 and about the fin structure 18 using a conventional chemical vapor deposition (CVD) process. The insulator material 22 can then be recessed to below a top surface of the fin structure 18 using conventional planarization techniques. It is preferable, though, that the insulator material 22 remains above the notch 20, about the semiconductor material 16.

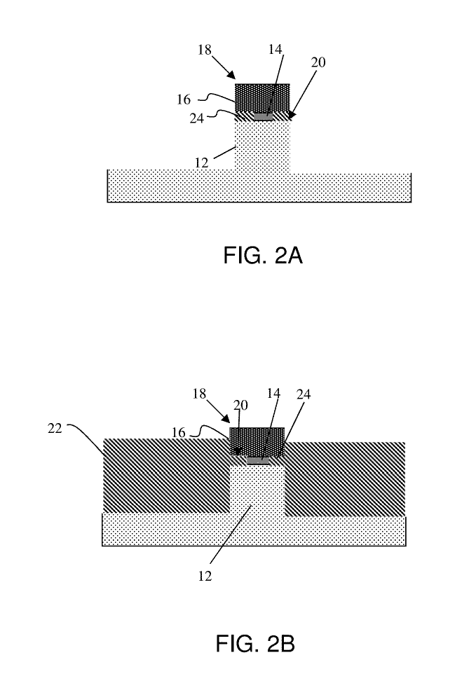

FIGS. 2A-2B show structures and respective fabrication processes for forming a notched fin structure in accordance with additional aspects of the present disclosure. In this embodiment, the semiconductor material 14 is preferably SiGe and the notch 20 can be filled with oxide material 24 using an oxidation process. For example, starting with the structure of FIG. 1C (e.g., after notch formation), the oxide material 24 can be formed in the notch 20 by placing the structure 10′ in an oxygen furnace followed by an annealing process, e.g., rapid thermal anneal (RTA) process. It should be understood by those of skill in the art that the oxidation rate is higher for Si material, hence allowing selective oxidation of the SiGe material 14. In this way, the SiGe material can be converted to oxide material 24, e.g., SiO₂, filling the notch 20.

As shown in FIG. 2B, the insulator material 22 is formed about the fin structure 18 and oxide material 24. As already described herein, the insulator material 22 can be an oxide material formed by an STI oxide gap fill process, e.g., CVD. The insulator material 22 can then be recessed to below a top surface of the fin structure 18 using conventional planarization techniques. It is preferably, though, that the insulator material 22 remains above the notch 20.

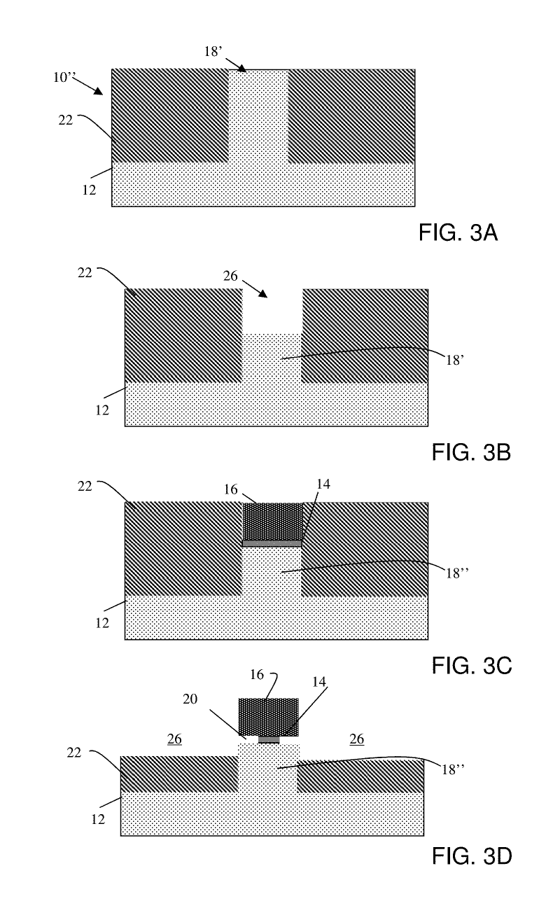

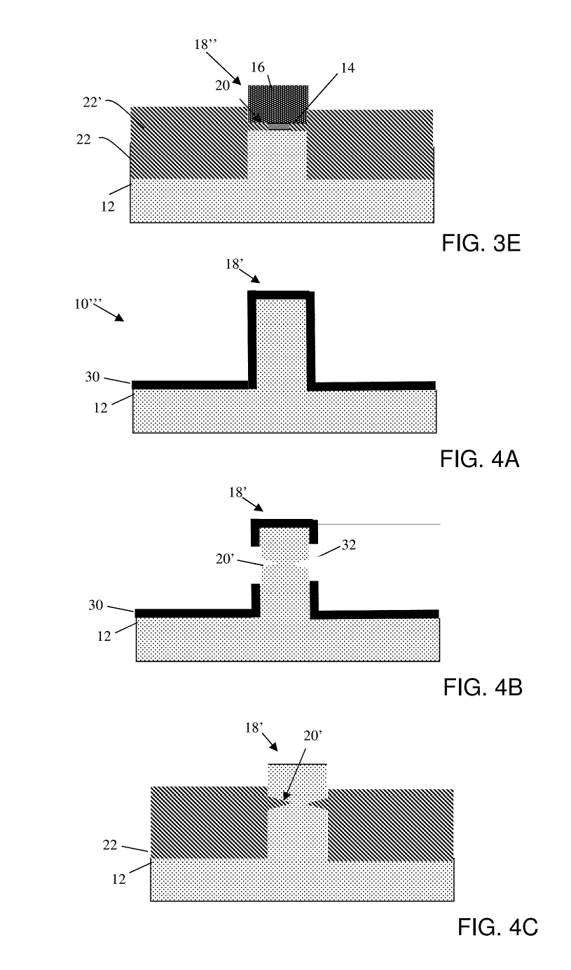

FIGS. 3A-3E show structures and respective fabrication processes for forming a notched fin structure in accordance with additional aspects of the present disclosure. In particular, FIG. 3A shows a beginning structure 10″ comprising a fin structure 18′ composed entirely of the substrate material 12, e.g., BULK Si. In embodiments, the fin structure 18′ is manufactured using conventional SIT techniques as already described herein. The insulator material 22 is formed about the fin structure 18′. As already described herein, the insulator material 22 can be an oxide material formed by an STI oxide gap fill process, e.g., CVD.

As shown in FIG. 3B, the fin structure 18′ can be recessed to form a trench 26 within the insulator material 22. In embodiments, the trench 26 can be formed through a conventional silicon etch back process, which does not require a mask. The trench 26 can be different depths, depending on the technology node. For example, the trench 26 can be about 20 nm to about 60 nm in depth; although other dimensions are also contemplated herein.

In FIG. 3C, a semiconductor material 14 is epitaxially grown directly on the substrate 12 and a semiconductor material 16 is epitaxially grown directly on the semiconductor material 14. In this way, a multi-layered fin structure 18″ is formed composed of layers 12, 14 and 16, similar to that described with respect to FIG. 1B. In embodiments, the semiconductor material 14 can be SiGe; although other semiconductor materials which are selective to the substrate material 12 and semiconductor layer 16 are also contemplated herein. For example, the semiconductor material 14 can be, e.g., SiGeC, SiC, SiP, GaAs, InAs, InP, etc. The semiconductor material 16 is preferably the same material as the substrate 12, and is preferably epitaxially grown in order to have a crystalline structure. The semiconductor material 16 should be a different material than the semiconductor material 14 such that a selective etching process can be performed to the semiconductor material 14 at later processing steps.

In FIG. 3D, a recess 28 is formed by recessing the insulator material 22 below a top surface of the fin structure 18. In embodiments, the recess 28 can be formed by using conventional planarization techniques. For example, the insulator material 22 can be recessed using a conventional oxide etch back process, which does not require a mask. It is preferable that the insulator material 22 be recessed to below the semiconductor material 14 of the fin structure 18″. The notch 20 is then formed in the fin structure 18″ by a selective etch process. For example, the notch 20 can be formed by a wet or dry etch process with chemistries that are selective to the semiconductor material 14. In embodiments, the notch 20 can be about 25% of the width of the fin structure 18″ depending on the technology node; although other dimensions are also contemplated based on specific device performance requirements.

In FIG. 3E, the insulator material 22′ is formed within the notch 20 and about the fin structure 18″. In embodiments, the insulator material 22′ can be an oxide material that is formed by an STI oxide gap fill process, e.g., CVD process. In an alternative method, the notch 20 can be filled by an oxidation process (as described with respect to FIG. 2A), followed by deposition, e.g., CVD, of the insulator material 22′ about the fin structure 18″. The insulator material 22 can then be recessed to below a top surface of the fin structure 18″ using conventional planarization techniques. It is preferably, though, that the insulator material 22′ remains above the notch 20.

FIGS. 4A-4C show structures and respective fabrication processes for forming a notched fin structure in accordance with additional aspects of the present disclosure. In particular, FIG. 4A shows a beginning structure 10″′ comprising a fin structure 18′ composed of the substrate material 12, e.g., BULK Si. In embodiments, the fin structure 18′ is manufactured using conventional SIT techniques as already described herein. The fin structure 18′ and an upper surface of the substrate 12 is lined with a hardmask material 30. In embodiments, the hardmask material 30 is a SiN material formed by a selective Plasma Enhanced Atomic Layer Deposition (PEALD) process. The hardmask material 30 can have a thickness of about 5 nm to about 10 nm; although other dimensions are contemplated herein.

In embodiments, the PEALD process can be tuned such that sidewalls of the fin structure 18′ can be etched faster than horizontal surfaces of the structure 10″′. In this way, as shown in FIG. 4B, portions of the hardmask material 30 on sidewalls of the fin structure 18′ can be etched back to expose the substrate material 12 of the fin structure 18′. Notches 20′ can be formed in the exposed substrate material, e.g., substrate 12, of the fin structure 18′ by a Si selective etch process. The notches 20′ can be, e.g., about 25% of the width of the fin structure 18′ depending on the technology node; although other dimensions are also contemplated based on specific device performance requirements.

As shown in FIG. 4C, the insulator material 22 is formed about the fin structure 18′ and within the notches 20′. As already described herein, the insulator material 22 can be an oxide material formed by an STI oxide gap fill process, e.g., CVD. The insulator material 22 can then be recessed to below a top surface of the fin structure 18′ using conventional planarization techniques. It is preferable, though, that the insulator material 22 remains above the notch 20′.

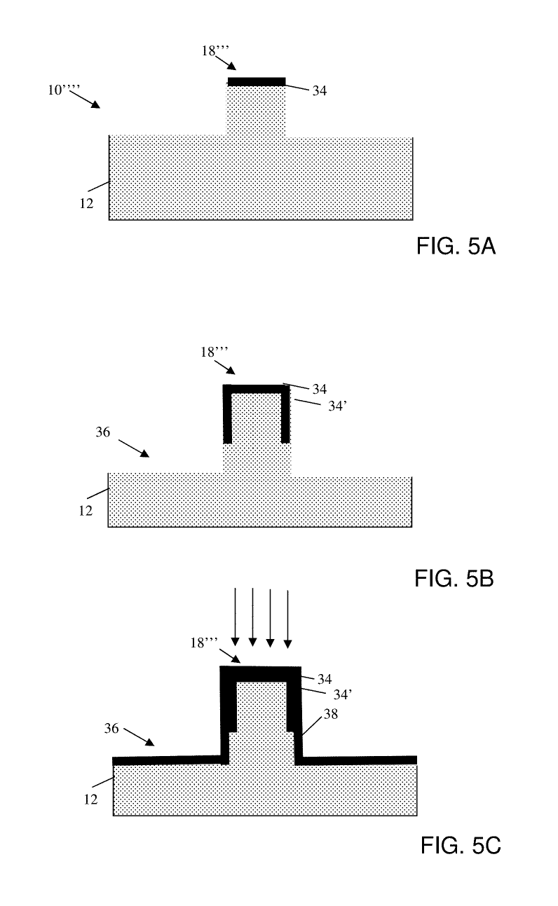

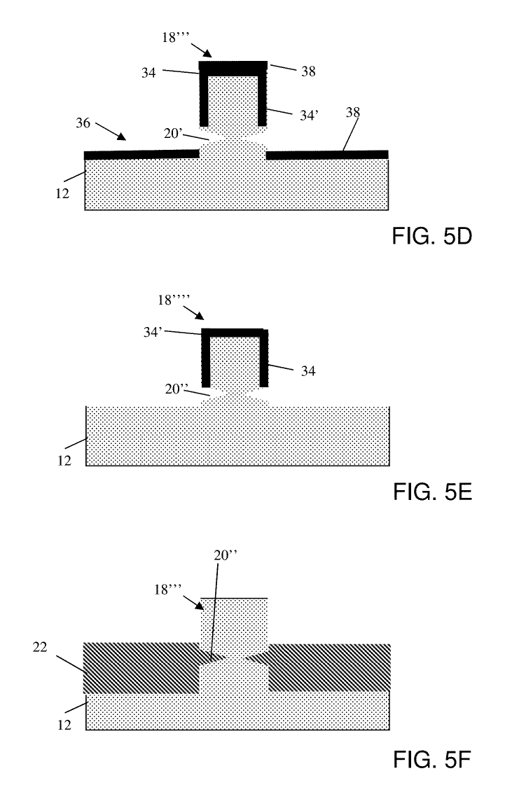

FIGS. 5A-5F show structures and respective fabrication processes for forming a notched fin structure in accordance with additional aspects of the present disclosure. In particular, FIG. 5A shows a beginning structure 10″′ comprising a partial fin structure 18″′ composed of the substrate material 12, e.g., BULK Si. In embodiments, the partial fin structure 18″′ can be manufactured using conventional SIT techniques as described herein. In further embodiments, an upper surface of the partial fin structure 18″′ can be formed to include a masking material 34, e.g., SiN. For example, prior to the SIT technique, the masking material 34, e.g., SiN, can be deposited onto the substrate material 12 using a conventional CVD process.

In FIG. 5B, additional masking material 34′ is deposited onto the partial fin structure 18″′. In embodiments, the additional masking material 34′ is a sidewall material, e.g., SiN, deposited by a blanket deposition process (e.g., CVD), followed by a conventional anisotropic etching process to remove the masking material 34′ from horizontal surfaces of the substrate 12. Following the anisotropic etching process, the substrate material 12 is recessed (as represented by reference numeral 36) using an oxide etch back process, with the masking material 34′ acting as a mask to protect the partial fin structure 18″′ during such etch back process.

In FIG. 5C, a material 38 is formed over the partial fin structure 18″′. In embodiment, the material 38 can be an insulator material and more preferably an oxide material deposited using a conventional deposition process. For example, the insulator material 38 can be deposited using an Atomic Layer Deposition (ALD) process to a thickness of about 3 nm to about 5 nm; although other dimensions are contemplated herein. The deposition process is followed by an Si implant process (as shown representatively by the arrows). The Si implant process, for example, will be provided only on the horizontal surfaces of the insulator material 38 resulting in a slower etch rate of these horizontal surfaces.

As shown in FIG. 5D, the insulator material 38 on the horizontal surfaces can be removed by a timed etching process to expose the underlying substrate material 12 of the partial fin structure 18″′. Notches 20″ can be formed in the exposed substrate material ,e.g., substrate 12, of the partial fin structure 18″′ by a Si selective etch process. The notches 20″ can be, e.g., about 25% of the width of the partial fin structure 18″′ depending on the technology node; although other dimensions are also contemplated based on specific device performance requirements.

In FIG. 5E, after formation of the notches 20″, the remaining portions of the insulator material 38 can be removed from the horizontal surfaces of the partial fin structure 18″′ and the surface of the substrate material 12. In embodiments, the insulator material 38 can be removed by a conventional etching process, e.g., RIE. The partial fin structure 18″′ will still be protected by the masking material 34, 34′, which allows for the partial fin structure 18″′ to remain protected during a final fin etching process.

As shown in FIG. 5F, a final fin structure 18″′ is formed by a final fin etching process selective to the substrate material 12. During this etching process, the masking material 34, 34′ will protect the fin structure from corrosion or damage. The masking material 34, 34′ can then be removed by a selective etch back process, for example, without the need for a mask. The insulator material 22 is then formed about the fin structure 18″′ and within the notches 20″. As already described herein, the insulator material 22 can be an oxide material formed by an STI oxide gap fill process, e.g., CVD. The insulator material 22 can then be recessed to below a top surface of the fin structure 18′ using conventional planarization techniques. It is preferable, though, that the insulator material 22 remains above the notch 20″.

Accordingly, by providing the notched finFET structures described herein, channel punch-through effect will be eliminated or significantly reduced. In this way, the finFET devices, e.g., NFET and PFET devices, will not suffer premature breakdown. Also, DC performance of both PFET and NFET devices can be improved due to higher Ieff@Vtsat. Moreover, the RO performance which is an NFET and PFET combined overall performance is also improved, namely Frequency@Iddq. As should be understood by those of skill in the art, Iddq is leakage of both the NFET and PFET devices and frequency is calculated based Ieff and Ceff of both devices. Here, the lower leakage, the lower capacitor and the higher Ieff will provide the improved RO performance.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure, comprising:
a fin structure composed of a substrate material and a stack of multiple epitaxially grown materials on the substrate material;
a notch formed in a first epitaxially grown material of the stack of multiple epitaxially grown materials of the fin structure; and
a single-type of insulator material within the notch of the fin structure and surrounding the fin structure on side surfaces of the first epitaxially grown material and above a surface of the notch on side surfaces of a second epitaxially grown material of the multiple epitaxially grown materials, which is above the first epitaxially grown material.

2. The structure of claim 1, wherein the stack of multiple epitaxially grown materials includes the first epitaxially grown material and the second epitaxially grown material directly on the first epitaxially grown material.

3. The structure of claim 2, wherein the first epitaxially grown material is different than the substrate material and the second epitaxially grown material.

4. The structure of claim 3, wherein the first epitaxially grown material is SiGe and the substrate material and the second epitaxially grown material are same materials.

5. The structure of claim 3, wherein the first epitaxially grown material is a first semiconductor material and the substrate material and the second epitaxially grown material are another semiconductor material.

6. The structure of claim 5, wherein the insulator material is an oxidization of the first semiconductor material.

7. The structure of claim 5, wherein the first semiconductor material is SiGe and the substrate material is Si bulk.

8. The structure of claim 1, wherein the notch is about 25% of a thickness of the fin structure.

9. (canceled)

10. A structure, comprising:
a fin structure composed of a single substrate material of bulk material;
a notch formed in the fin structure; and
a single type insulator material within the notch of the fin structure and surrounding the single substrate material, above and below the notch.

11.-13. (canceled)

14. The structure of claim 10, wherein the insulator material in the notch is an oxidization of the SiGe.

15. The structure of claim 10, wherein the insulator material in the notch is an oxidization of the single substrate material.

16. The structure of claim 10, wherein the notch is about 25% of a thickness of the fin structure.

17.-20 (canceled)

21. The structure of claim 2, wherein the insulator material within the notch and surrounding the fin structure and above the surface of the notch is an oxide material.

22. The structure of claim 21, wherein the insulator material is recessed below a top surface of the second epitaxially grown material.

23. The structure of claim 10, wherein the insulator material within the notch and surrounding the portion of the single substrate material is an oxide material.

24. The structure of claim 23, wherein the insulator material is recessed below a top surface of the single substrate material.
